(19) United States
(12) Patent Application Publication
(10) Pub. No.: US 2026/0334342 A1
(43) Pub. Date: Oct. 22, 2026

(54) NON-CONDUCTIVE FILM LASER GROOVE FOR SEMICONDUCTOR DIE MANUFACTURING

(71) Applicant: Micron Technology, Inc., Boise, ID (US)

(72) Inventors: Ankur Harish SHAH, Singapore (SG); Mei Wen LU, Taichung City (TW); Liang Chun FU, Taichung City (TW); Yi Chin TSAI, Taichung (TW); Wen How SIM, Singapore (SG); Harjashan Veer SINGH, South Richmond Hill, NY (US)

(21) Appl. No.: 19/541,457

(22) Filed: Feb. 17, 2026

Related U.S. Application Data
(60) Provisional application No. 63/790,410, filed on Apr. 17, 2025.

(51) Int. Cl. H10W 90/00; H10W 74/10; H10W 90/20

(52) U.S. Cl. CPC H10W 90/724; H10W 74/129; H10W 90/297; H10W 90/756

(57) ABSTRACT

A semiconductor device assembly includes a semiconductor die comprising a wafer assembly having one or more wafer layers, the wafer assembly having a first and second main surfaces. The wafer assembly includes: a shelf arranged at least partially around an outer periphery of the wafer assembly and arranged at a predefined depth of the wafer assembly, wherein the shelf delineates a change in a cross-sectional width of the wafer assembly; one or more first sidewalls arranged above the shelf, the one or more first sidewalls extending between the shelf and the first main surface; and one or more second sidewalls arranged below the shelf, the one or more second sidewalls extending between the shelf and the second main surface. The semiconductor device assembly includes a non-conductive film (NCF) arranged on the first main surface, wherein the NCF includes a film groove at an outer edge of the NCF.

### CROSS-REFERENCE TO RELATED APPLICATION

This Patent Application claims priority to U.S. Provisional Patent Application No. 63/790,410, filed on Apr. 17, 2025, entitled “NON-CONDUCTIVE FILM LASER GROOVE FOR SEMICONDUCTOR DIE MANUFACTURING,” and assigned to the assignee hereof. The disclosure of the prior Application is considered part of and is incorporated by reference into this Patent Application.

### TECHNICAL FIELD

The present disclosure generally relates to semiconductor devices and methods of forming semiconductor devices. For example, the present disclosure relates to forming a non-conductive film (NCF) laser groove for semiconductor die manufacturing.

### BACKGROUND

A semiconductor package may include a semiconductor substrate, one or more semiconductor electronic components coupled to and/or embedded in the semiconductor substrate, and a casing formed over the semiconductor substrate to encapsulate the one or more semiconductor electronic components. The one or more semiconductor electronic components may be interconnected by electrical interconnects to form one or more semiconductor devices, such as one or more integrated circuits (ICs) (e.g., one or more dies or chips). For example, the semiconductor electronic components and the electrical interconnects may be fabricated on a semiconductor wafer to form one or more ICs before being diced into dies or chips and then packaged. A semiconductor package may be referred to as a semiconductor chip package that includes one or more ICs. A semiconductor package protects the semiconductor electronic components and the electrical interconnects from damage and includes a mechanism for connecting the semiconductor electronic components and the electrical interconnects to external components (e.g., a circuit substrate), such as via balls, pins, leads, contact pads, or other electrical interconnect structures. A semiconductor device assembly may be or may include a semiconductor package, multiple semiconductor packages, and/or one or more components of a semiconductor package (e.g., one or more semiconductor devices with or without a casing).

An electronic system assembly may include multiple semiconductor packages electrically coupled to a carrier substrate (e.g., circuit substrate). An electronic system assembly may include additional system components electrically coupled to the carrier substrate. The carrier substrate may include electrical interconnects and conductive paths used for interconnecting system components, including the multiple semiconductor packages and other system components of the electronic system assembly. Accordingly, the multiple semiconductor packages may be electrically connected to each other and/or to one or more additional system components via the carrier substrate to form the electronic system assembly. By way of example, other system components may include passive components (e.g., storage capacitors), processing units (e.g., a central processing unit (CPU), a graphics processing unit (GPU), a microprocessor, and/or a microcontroller), control units (e.g., a microcontroller, a memory controller, and/or a power management controller), or one or more other electronic components.

### BRIEF DESCRIPTION OF THE DRAWINGS

FIGS. 1A through 1H are cross-sectional views showing formation of semiconductor device assemblies at example process stages of an example process of forming the semiconductor device assemblies.

FIG. 2 shows a cross-sectional view of a semiconductor device assembly according to one or more implementations.

FIG. 3 is a flowchart of an example method of forming an integrated assembly or a memory device, including forming an NCF laser groove during semiconductor die manufacturing.

### DETAILED DESCRIPTION

In semiconductor manufacturing, particularly during the die preparation phase of assembly, an important step involves the separation of individual dies from a silicon wafer. This process, known as die singulation, typically involves dicing techniques to segment the wafer. Prior to die singulation, a non-conductive film (NCF) may be applied on top of the wafer. The NCF may be used as a bonding material or adhesive for vertical stacking of dies. Thus, the NCF may be used to bond one die on top on another die. The conventional processes can lead to a range of issues that affect manufacturing yield and quality of the singulated dies. Problems can arise during die singulation from a viscoelastic nature of the NCF, which may stretch and retain high stress during separation, leading to uneven breakage, NCF tearing, and recoil effects. These issues can manifest as defects, such as incomplete or uneven separation of dies, misalignment of die edges, silicon chipping or cracking at the die edges, and the generation of particulate (e.g., silicon particles) due to die knocking. Particles generated during die separation may drift over the individual dies and land on areas of the individual dies that may cause reliability issues, such as shorts and other operability errors. As a result, yield losses can be significant, with particular processes experiencing losses greater than 20% due to one or more of the defects. Thus, there is a need for an improved method that ensures uniform separation of dies with no or minimal damage at the die edges and reduced particulate generation, thereby substantially reducing yield loss.

Some implementations described herein provide a method for improving the yield in semiconductor die manufacturing by using a low-power laser to form a groove in an NCF that is arranged on a top surface of a wafer. The method may include providing a wafer with die regions delineated by wafer scribe regions, forming a wafer groove in the wafer scribe regions, and then applying an NCF on the top surface of the wafer and over the wafer groove. A low-power laser beam is then used to groove the NCF to form a film groove in the NCF in a region of the NCF that is arranged over the wafer groove. The film groove facilitates a separation of the die regions for forming individual dies, thereby improving an even separation of dies in the wafer scribe regions, reducing damage to die sidewalls of the individual dies (e.g., due to reduced NCF recoil effects), and/or reducing particulate generation during wafer/die separation.

Additionally, the method may include forming weakened structural regions in the wafer along scribe lines (e.g., singulation lanes) that are aligned with the wafer scribe regions. The weakened structural regions may further facilitate the separation of the die regions for forming the individual dies, enabling a clean, straight break between die regions. For example, the weakened structural regions may be formed by emitting laser beams into the wafer at predefined depths in accordance with a stealth dicing process step. Stealth dicing employs a laser to create internal modifications within the wafer, along singulation lanes, without cutting through the wafer. The internal modifications form weakened structural regions. In other words, stealth dicing uses a laser to create a modified layer within the wafer, along the scribe lines.

After a laser process creates the internal modifications, the wafer undergoes a mechanical separation process, which may include using a tape expander, a stretching tape, or another type of expander that is attached to a bottom surface of the wafer. Thus, the wafer may be arranged on an expander to facilitate separation. During the mechanical separation process, the wafer is stretched or stressed, causing micro-cracks to propagate and split the wafer along the scribe lines through or near the weakened structural regions and resulting in the die regions being separated into the individual dies.

According to the method, the laser beams used for forming the weakened structural regions may be emitted after the NCF is disposed on the top surface of the wafer, but before the low-power laser beam is used to groove the NCF to form the film groove. The low-power laser beam may have a lower power than the laser beams used for forming the weakened structural regions.

Implementations described herein also extend to a structure of a semiconductor device assembly that includes the NCF with a unique film groove at an edge of the semiconductor device assembly.

In this way, the low-power laser grooving of the NCF provides a controlled method to weaken the NCF material at specific locations, ensuring that when the wafer is separated into individual dies, the wafer separation is more precise, cleaner, and less susceptible to die edge defects that are more prevalent without the film groove. The method may provide a reduced yield loss from over 20%, as is typical in separation techniques that do not form the film groove, to under 5%, resulting in a significant increase in manufacturing yield, improved die gap performance, and minimized silicon particle generation due to less recoil. Moreover, the method does not necessitate additional equipment or create capacity constraints. By improving the quality and/or the reliability of the semiconductor device assembly, an amount of resources used to support a market for producing the semiconductor device assembly (e.g., raw materials, semiconductor manufacturing tools, labor, and/or computing resources) may be reduced.

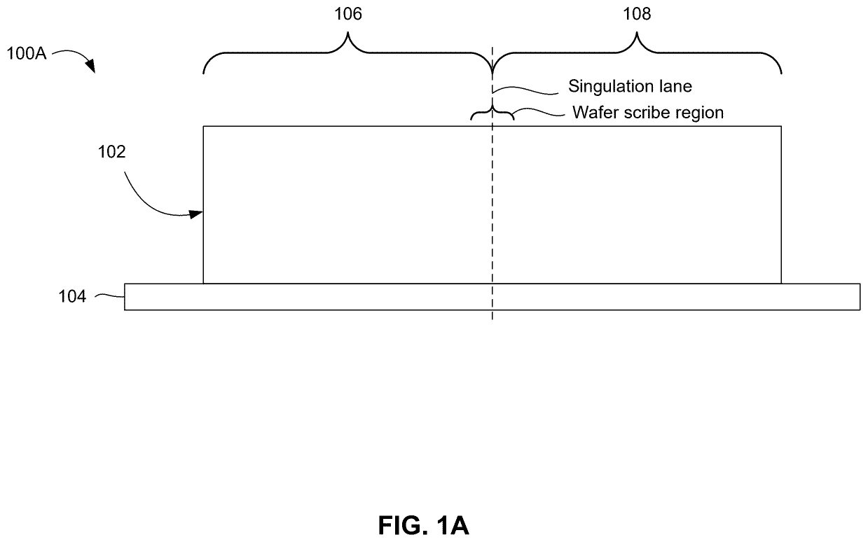

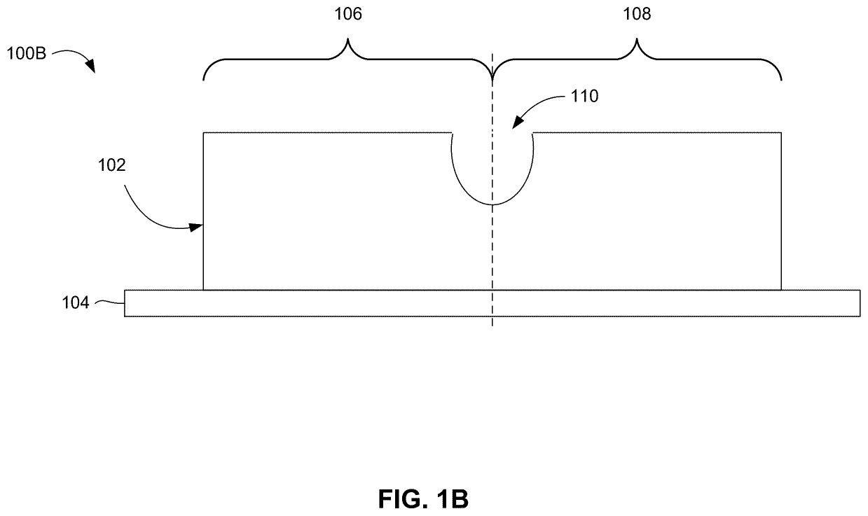

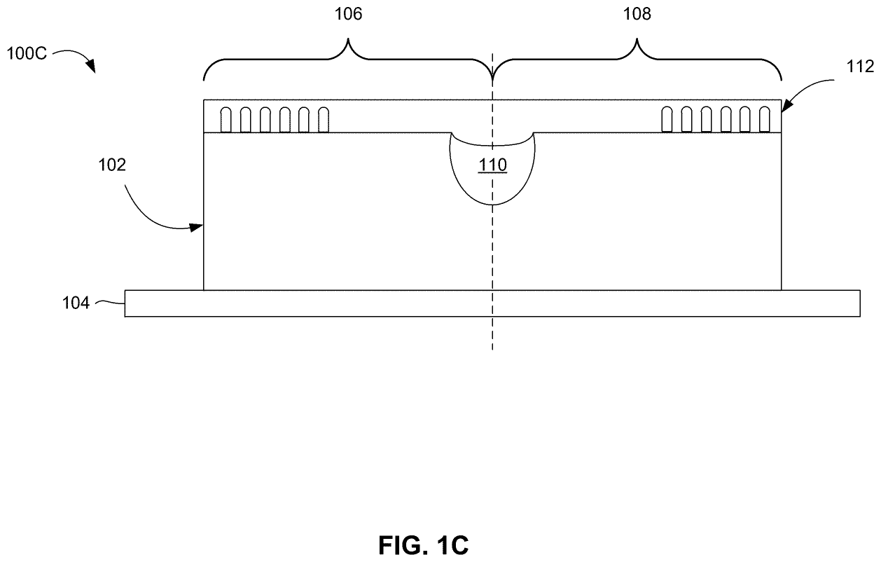

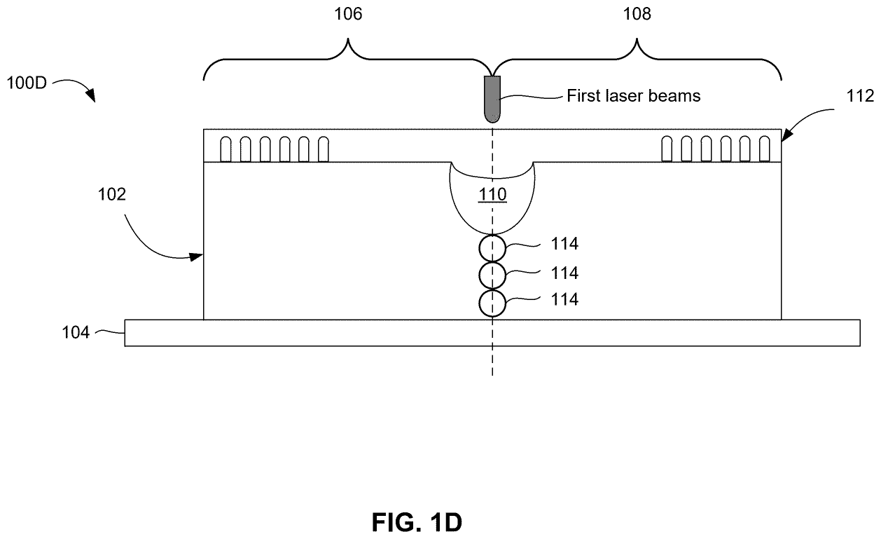

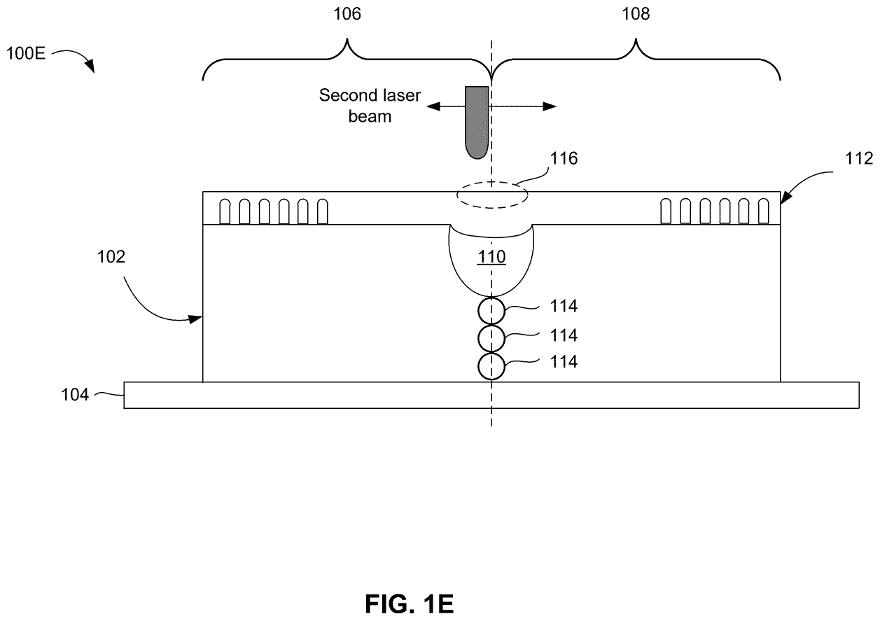

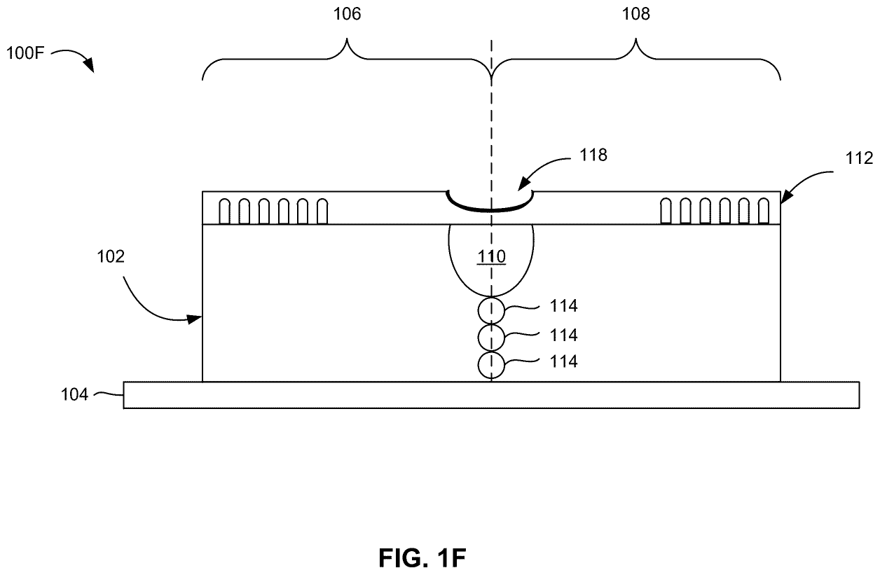

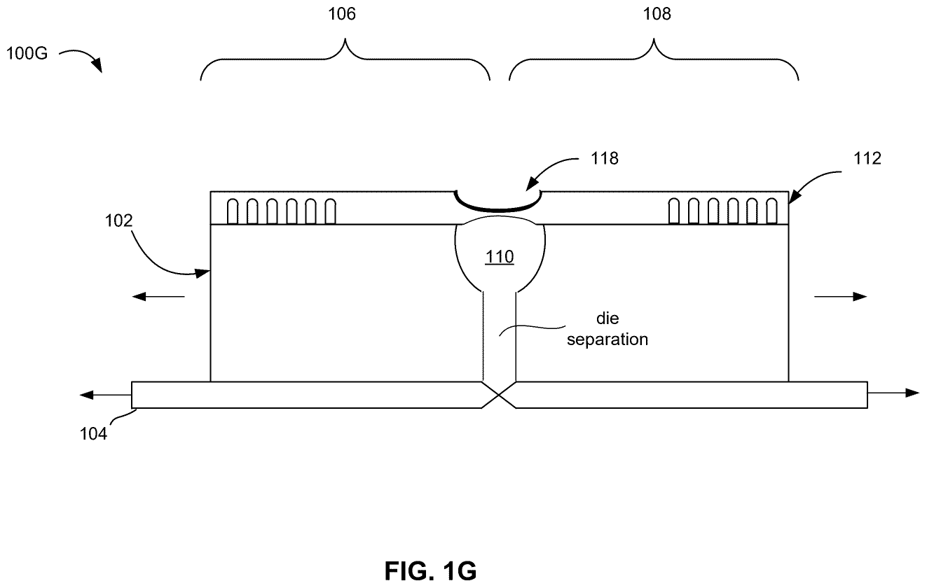

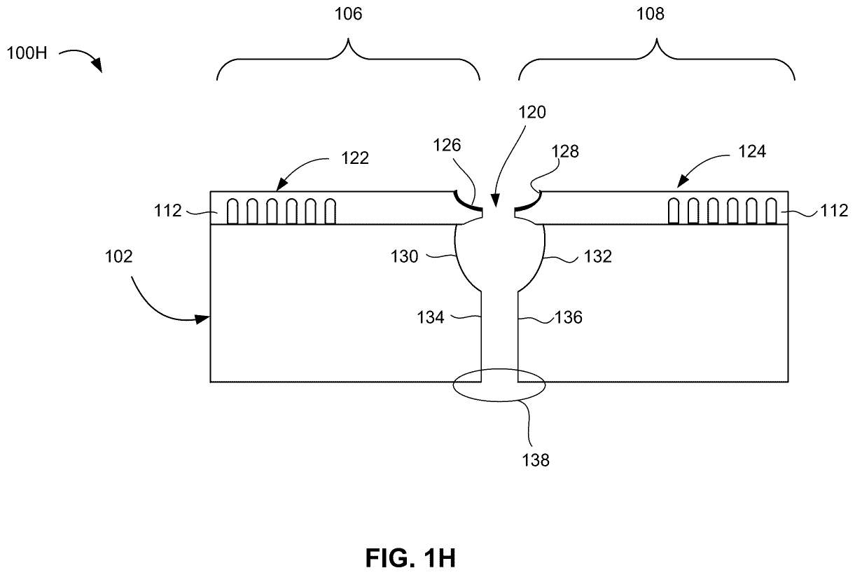

FIGS. 1A through 1H are cross-sectional views showing formation of semiconductor device assemblies at example process stages of an example process of forming the semiconductor device assemblies. In some implementations, the semiconductor device assemblies may be semiconductor dies (sometimes called dies or a chips) or semiconductor device assemblies that include respective dies. In some implementations, the example process described below in connection with FIGS. 1A through 1H may correspond to a method of manufacturing a semiconductor device assembly that includes a die or two or more dies arranged in a vertical stack (e.g., a die stack). However, the process described below is an example, and other example processes may be used to form the structure, an integrated assembly that includes the structure, and/or one or more parts of the structure and/or the integrated assembly.

As shown in FIG. 1A, the process may include a process stage 100A that includes providing a wafer 102 onto an expander 104. The wafer 102 may be include one or more wafer layers. For example, the wafer 102 may be a semiconductor wafer, such as a silicon wafer. In some implementations, the wafer 102 may be formed by bonding one or more wafer layers together. In some cases, one or more insulation layers, such as dielectric layers, may be included in the wafer layers. The wafer 102 may have a first main surface 102a (e.g., a first wafer surface, such as a top surface) and a second main surface 102b (e.g., a second wafer surface, such as a bottom surface) arranged opposite to the first main surface 102a. Thus, the second main surface 102b may be arranged or otherwise provided on the expander 104. In addition, the wafer 102 includes a plurality of die regions, including a first die region 106 and a second die region 108 delineated by a wafer scribe region. Accordingly, the wafer 102 may be a wafer assembly that includes one or more wafer layers and a plurality of die regions delineated by wafer scribe regions or singulation lanes.

As shown in FIG. 1B, the process may include a process stage 100B that includes forming a wafer groove 110 in the wafer scribe region. The wafer groove 110 extends from the first main surface 102a into the wafer 102 such that a first portion of the wafer groove 110 is located in the first die region 106 and a second portion of the wafer groove 110 is located in the second die region 108. In some implementations, the wafer groove 110 may be formed by a wafer etching process. In some implementations, the wafer groove 110 may be a wafer trench. The wafer groove 110 may have a curved or a straight (e.g., horizontally flat) groove bottom (or trench bottom).

As shown in FIG. 1C, the process may include a process stage 100C that includes forming an NCF 112 on the first main surface 102a to cover both the first die region 106 and the second die region 108. The NCF 112 also covers the wafer groove 110. Thus, a portion of the NCF 112 is arranged or otherwise suspended over the wafer groove 110. The NCF 112 may be a bonding layer or an adhesive layer used for bonding additional dies to individual dies after die separation. For example, once the wafer 102 is separated into individual dies, a die may be stacked on one of the individual dies to form a die stack. During die stacking, heat and pressure may be applied during a die bonding process. As a result of the applied heat and pressure, the NCF flows, filling any gaps between dies. The NCF may then be allowed to cool such that the NCF solidifies to form a secure, void-free interface between the dies.

As shown in FIG. 1D, the process may include a process stage 100D that includes emitting first laser beams into the wafer 102 to form weakened structural regions 114 in the wafer 102 along a scribe line that is aligned with the wafer scribe region. The first laser beams may be associated with a stealth dicing process, and the weakened structural regions 114 may be laser-induced internal modifications formed within the wafer 102 by the first laser beams.

For example, the first laser beams may be emitted into the wafer 102 during stealth dicing to create weakened structural regions 114 (e.g., defect regions) in the wafer 102, the weakened structural regions 114 being aligned with the scribe lanes. The weakened structural regions 114 may be formed at different depths within the wafer 102. In order to provide a clean, smooth, and precise separation of the first die region 106 and the second die region 108 (e.g., to form individual dies) during a mechanical die separation process, the weakened structural regions 114 should be vertically aligned and formed at optimized depths.

As shown in FIGS. 1E and 1F, the process may include process stages 100E and 100F that include emitting a second laser beam onto a region 116 of an upper surface of the NCF 112 to form a film groove 118 in the NCF 112. The second laser beam may be focused onto the upper surface of the NCF 112 to remove (only) a portion of the NCF 112 within the region 116 disposed above the wafer groove 110 to form the film groove 118. Thus, the second laser beam is a low-power laser beam with sufficient power to remove the portion of the NCF 112 within the region 116, but with power low enough as to not penetrate through the NCF 112 and cause the NCF 112 to break apart. The second laser beam may have a higher optical power than an optical power of the first laser beams, which pass through the NCF 112 to form the weakened structural regions 114 without removing material from the NCF 112.

As shown in FIG. 1E, the second laser beam may be moved horizontally across the upper surface of the NCF 112 to form the film groove 118 over the wafer groove 110. The horizontal movement of the second laser beam across the upper surface of the NCF 112 may be used to widen a width of the film groove 118. The film groove 118 may provide a thinned or weakened area of the NCF 112 that is arranged over the wafer scribe region and aligned with the scribe line (e.g., over the wafer groove 110). In some examples, the film groove 118 may be concaved such that a thinnest or weakest portion of the NCF 112 is aligned with the scribe line.

As shown in FIG. 1G, the process may include a process stage 100G that includes separating the first die region 106 and the second die region 108 along the weakened structural regions 114 to form individual dies (e.g., a first die 106′ and a second die 108′, respectively). Separating the first die region 106 and the second die region 108 along the weakened structural regions 114 may include stretching the expander 104 in opposite lateral directions to cause the first die region 106 and the second die region 108 to separate along the weakened structural regions 114. Stretching the expander 104 causes the first die region 106 and the second die region 108 to pull apart, during which the NCF 112 also stretches in opposite lateral directions. Stretching the expander 104 also causes the weakened area of the NCF 112, below the film groove 118, to stretch and eventually split apart, thereby forming an opening 120 through the NCF 112.

As shown in FIG. 1H, the process may include a process stage 100H in which the first die 106′ and the second die 108′ are formed from the separation. As a result of the separating process step, the NCF 112 separates into two NCF portions, as shown in FIG. 1H, such that a first portion 122 of the NCF 112 is arranged on the first die 106′ and a second portion 124 of the NCF 112 is arranged on the second die 108′. Thus, the first die 106′ includes the first portion 122 of the NCF 112, the first portion 122 of the NCF 112 having a first portion 126 of the film groove 118 at a die edge of the first die 106′. Additionally, the second die 108′ includes the second portion 124 of the NCF 112, the second portion 124 of the NCF 112 having a second portion 128 of the film groove 118 at a die edge of the second die 108′. In addition, after separating the first die region 106 and the second die region 108, the first die 106′ includes a first portion 130 of the wafer groove 110, and the second die 108′ includes a second portion 132 of the wafer groove 110. The first die 106′ includes a first straight sidewall 134 that extends from a bottom of the first portion 130 of the wafer groove 110 to a bottom surface of the first die 106′. Additionally, the second die 108′ includes a second straight sidewall 136 that extends from a bottom of the second portion 132 of the wafer groove 110 to a bottom surface of the second die 108′.

The film groove 118 enables even and consistent separation of the NCF 112 into the first portion 122 and the second portion 124. The first portion 122 and the second portion 124 may split substantially at the scribe line, at a center of the wafer scribe region. Thus, the film groove 118 enables even separation and consistent separation of the first die 106′ and the second die 108′. Additionally, the film groove 118 reduces an amount of recoil by the first die 106′ and the second die 108′ that is induced by the NCF 112 while separating the first die region 106 and the second die region 108 along the weakened structural regions 114. In other words, the film groove 118 enables the NCF 112 to split apart with less force. As a result, the NCF 112 does not retain as much elastic stress (energy), which can cause the first die 106′ and the second die 108′ to recoil back toward each other, which may cause damage at the die edges (e.g., cracking or chipping) and/or additional particulate generation due to die knocking. For example, without the film groove 118, the first die 106′ and the second die 108′ may be more susceptive to die knocking in region 138, which may cause cracking, chipping, and/or particulate generation in the region 138. The film groove 118 reduces cracking, chipping, and/or particulate generation in the region 138.

Accordingly, the film groove 118 reduces an amount of damage to the sidewalls 134 and 136 of the dies while the first die region 106 and the second die region 108 are being separated along the weakened structural regions 114. Additionally, the film groove 118 reduces an amount of particulate generated while separating the first die region 106 and the second die region 108 along the weakened structural regions 114. For example, die knocking and uneven die separation may lead to additional particulate being generated. According, the process may improve the yield in semiconductor die manufacturing (e.g., reduce yield loss) by using a low-power laser to form the film groove 118 in the NCF 112 that is arranged on a top surface of the wafer 102.

In addition, the process may include stacking two or more dies to form a die stack, with at least one of the dies being manufactured according to the process steps described in connection with FIGS. 1A through 1H. For example, two dies may be bonded together using thermal compression bonding (TCB), using an NCF as a bonding material to bond the two dies in a vertical arrangement.

As indicated above, the process steps described in connection with FIGS. 1A through 1H are provided as examples. Other examples may differ from what is described with respect to FIGS. 1A through 1H. The structures shown in FIG. 1H may be equivalent to structures described elsewhere herein. In process steps above that describe forming material, such material may be formed, for example, using chemical vapor deposition, atomic layer deposition, physical vapor deposition, or another deposition technique. In process steps above that describe removing material, such material may be removed, for example, using a wet etching technique (e.g., wet chemical etching), a dry etching technique (e.g., plasma etching), an ion etching technique (e.g., sputtering or reactive ion etching), atomic layer etching, another etching technique, or laser grooving, consistent with the process steps described above.

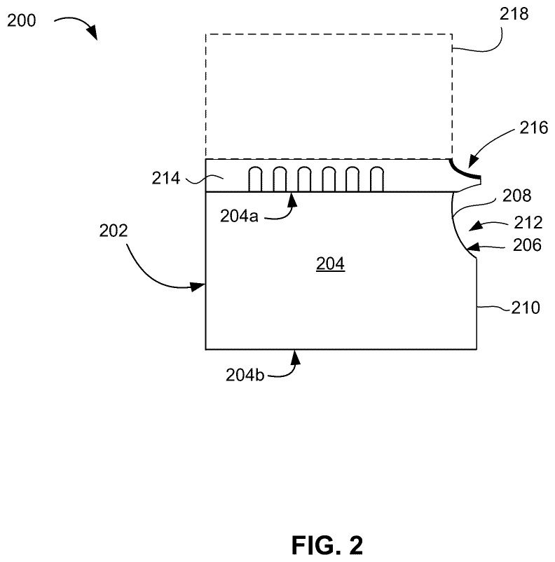

FIG. 2 shows a cross-sectional view of a semiconductor device assembly 200 according to one or more implementations. The semiconductor device assembly 200 may be manufactured according to the process steps described in connection with FIGS. 1A through 1H. For example, the semiconductor device assembly 200 may include one or more dies manufactured according to the process steps described in connection with FIGS. 1A through 1H.

The semiconductor device assembly 200 may include any type of device or system that includes one or more semiconductor dies. For example, the semiconductor device assembly 200 may include a memory device, a flash memory device, a NAND memory device, a NOR memory device, a random access memory (RAM) device, a read-only memory (ROM) device, a dynamic RAM (DRAM) device, a static RAM (SRAM) device, a solid state drive (SSD), a microchip, and/or a system on a chip (SoC), among other examples. In some cases, the semiconductor device assembly 200 may be referred to as a semiconductor package, an assembly, a semiconductor device assembly, or an integrated assembly. Moreover, a semiconductor die may include any type of circuit, such as an analog circuit, a digital circuit, a controller (e.g., a microcontroller), a radiofrequency (RF) circuit, a power supply, a power management circuit, an input-output (I/O) chip, an application-specific integrated circuit (ASIC), a field-programmable gate array (FPGA), and/or a memory device (e.g., a NAND memory device, a NOR memory device, a RAM device, or a ROM device).

The semiconductor device assembly 200 includes a first die 202 comprising a wafer assembly 204 having one or more wafer layers, the wafer assembly 204 having a first main surface 204a (e.g., a top surface) and a second main surface 204b (e.g., a bottom surface) arranged opposite to the first main surface 204a. The wafer assembly 204 includes a shelf 206 arranged at least partially around an outer periphery of the wafer assembly 204 and arranged at a predefined depth d of the wafer assembly 204. The shelf 206 may correspond to a bottom portion of the wafer groove 110 described in connection with FIGS. 1A through 1H. The shelf 206 delineates a change in a cross-sectional width of the wafer assembly 204. For example, the wafer assembly 204 may have a first cross-sectional width above the shelf 206 and a second cross-sectional width below the shelf 206, the first cross-sectional width being less than the second cross-sectional width, as shown in FIG. 2.

The wafer assembly 204 further includes one or more first sidewalls 208 arranged above the shelf 206, with the first sidewalls 208 extending between the shelf 206 and the first main surface 204a. The wafer assembly 204 further includes one or more second sidewalls 210 arranged below the shelf 206, with the second sidewalls 210 extending between the shelf 206 and the second main surface 204b. The first sidewalls 208 and the shelf 206 may be part of an exterior wafer groove 212 (or exterior wafer trench). In the example shown in FIG. 2, the shelf 206 is curved (has a curved profile). However, in other examples, the shelf 206 may be straight (have a straight profile). In some implementations, the shelf 206 may be horizontal, such that the shelf is substantially parallel to the first main surface 204a and the second main surface 204b.

The semiconductor device assembly 200 further includes an NCF 214 arranged on the first main surface 204a. The NCF 214 includes a film groove 216 at an outer edge of the NCF 214. The outer edge of the NCF 214 at which the film groove 216 is located may protrude laterally from the one or more first sidewalls 208. Thus, the outer edge of the NCF 214 at which the film groove 216 is located may protrude laterally over the shelf 206 such that the film groove 216 is arranged over the shelf 206. In some implementations, the film groove 216 is concave and narrows toward a lateral side of the NCF 214.

The semiconductor device assembly 200 may include a second die 218 arranged on the NCF 214, forming a die stack. The NCF 214 may bond the first die 202 (e.g., the wafer assembly 204 of the first die 202) to the second die 218.

As indicated above, FIG. 2 is provided as an example. Other examples may differ from what is described with regard to FIG. 2.

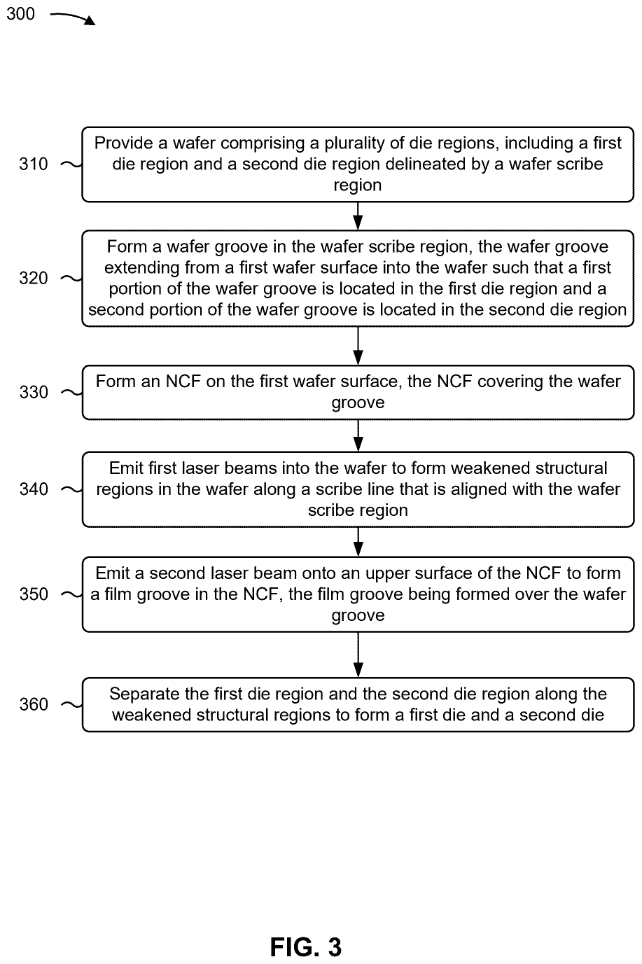

FIG. 3 is a flowchart of an example method 300 of forming an integrated assembly or a memory device, including forming an NCF laser groove during semiconductor die manufacturing. In some implementations, one or more process blocks of FIG. 3 may be performed by various semiconductor manufacturing equipment.

As shown in FIG. 3, the method 300 may include providing a wafer comprising a plurality of die regions, including a first die region and a second die region delineated by a wafer scribe region (block 310). As further shown in FIG. 3, the method 300 may include forming a wafer groove in the wafer scribe region, the wafer groove extending from a first wafer surface into the wafer such that a first portion of the wafer groove is located in the first die region and a second portion of the wafer groove is located in the second die region (block 320). As further shown in FIG. 3, the method 300 may include forming an NCF on the first wafer surface, the NCF covering the wafer groove (block 330). As further shown in FIG. 3, the method 300 may include emitting first laser beams into the wafer to form weakened structural regions in the wafer along a scribe line that is aligned with the wafer scribe region (block 340). As further shown in FIG. 3, the method 300 may include emitting a second laser beam onto an upper surface of the NCF to form a film groove in the NCF, the film groove being formed over the wafer groove (block 350). As further shown in FIG. 3, the method 300 may include separating the first die region and the second die region along the weakened structural regions to form a first die and a second die, respectively (block 360). Separating the first die region and the second die region along the weakened structural regions includes separating the NCF, at the film groove, into two NCF portions.

The method 300 may include additional aspects, such as any single aspect or any combination of aspects described below and/or in connection with one or more other methods described elsewhere herein.

In a first aspect, forming the wafer groove includes a wafer etching process.

In a second aspect, alone or in combination with the first aspect, the second laser beam is focused onto the upper surface of the NCF to remove a portion of the NCF above the wafer groove to form the film groove.

In a third aspect, alone or in combination with one or more of the first and second aspects, the second laser beam is a low-power laser.

In a fourth aspect, alone or in combination with one or more of the first through third aspects, the first die and the second die are memory dies.

In a fifth aspect, alone or in combination with one or more of the first through fourth aspects, the film groove reduces an amount of particulate generated while separating the first die region and the second die region along the weakened structural regions.

In a sixth aspect, alone or in combination with one or more of the first through fifth aspects, the film groove reduces an amount of damage to sidewalls of the first die and the second die while the first die region and the second die region are being separated along the weakened structural regions.

In a seventh aspect, alone or in combination with one or more of the first through sixth aspects, the film groove reduces an amount of recoil by the first die and the second die that is induced by separating the first die region and the second die region along the weakened structural regions.

In an eighth aspect, alone or in combination with one or more of the first through seventh aspects, the first laser beams are associated with a stealth dicing process, and the weakened structural regions are internal modifications formed within the wafer by the first laser beams.

In a ninth aspect, alone or in combination with one or more of the first through eighth aspects, the method 300 includes, prior to forming the NCF on the first wafer surface of the wafer, arranging a second wafer surface of the wafer onto an expander, the second wafer surface being opposite to the first wafer surface, wherein separating the first die region and the second die region along the weakened structural regions includes stretching the expander in opposite lateral directions to cause the first die region and the second die region to separate along the weakened structural regions.

In a tenth aspect, alone or in combination with one or more of the first through ninth aspects, after separating the first die region and the second die region, the first die includes a first portion of the NCF, the first portion of the NCF having a first portion of the film groove, and the second die includes a second portion of the NCF, the second portion of the NCF having a second portion of the film groove.

In an eleventh aspect, alone or in combination with one or more of the first through tenth aspects, after separating the first die region and the second die region, the first die includes a first portion of the wafer groove, and the second die includes a second portion of the wafer groove.

In a twelfth aspect, alone or in combination with one or more of the first through eleventh aspects, after separating the first die region and the second die region, the first die includes a first straight sidewall that extends from a bottom of the first portion of the wafer groove to a bottom surface of the first die, and the second die includes a second straight sidewall that extends from a bottom of the second portion of the wafer groove to a bottom surface of the second die.

Although FIG. 3 shows example blocks of the method 300, in some implementations, the method 300 may include additional blocks, fewer blocks, different blocks, or differently arranged blocks than those depicted in FIG. 3.

In some implementations, a method of manufacturing a semiconductor device assembly includes providing a wafer comprising a plurality of die regions, including a first die region and a second die region delineated by a wafer scribe region; forming a wafer groove in the wafer scribe region, the wafer groove extending from a first wafer surface into the wafer such that a first portion of the wafer groove is located in the first die region and a second portion of the wafer groove is located in the second die region; forming an NCF on the first wafer surface, the NCF covering the wafer groove; emitting first laser beams into the wafer to form weakened structural regions in the wafer along a scribe line that is aligned with the wafer scribe region; emitting a second laser beam onto an upper surface of the NCF to form a film groove in the NCF, the film groove being formed over the wafer groove; and separating the first die region and the second die region along the weakened structural regions to form a first die and a second die, respectively, wherein separating the first die region and the second die region along the weakened structural regions includes separating the NCF, at the film groove, into two NCF portions.

In some implementations, a method of manufacturing a semiconductor device assembly includes forming a wafer groove in a wafer scribe region of a wafer, wherein the wafer includes a first die region and a second die region delineated by the wafer scribe region, and wherein the wafer groove extends from a first wafer surface into the wafer such that a first portion of the wafer groove is located in the first die region and a second portion of the wafer groove is located in the second die region; forming an NCF on the first wafer surface, the NCF being arranged over the wafer groove; emitting a laser beam onto an upper surface of the NCF to form a film groove in the NCF, the film groove being formed over the wafer groove; and separating the wafer along a scribe line that is associated with the wafer scribe region such that the first die region is separated from the second die region to form a first die and a second die, respectively, wherein separating the wafer along the scribe line includes separating the NCF, at the film groove, into two NCF portions.

In some implementations, a semiconductor device assembly includes a semiconductor die comprising a wafer assembly having one or more wafer layers, the wafer assembly having a first main surface and a second main surface arranged opposite to the first main surface, wherein the wafer assembly includes: a shelf arranged at least partially around an outer periphery of the wafer assembly and arranged at a predefined depth of the wafer assembly, wherein the shelf delineates a change in a cross-sectional width of the wafer assembly; one or more first sidewalls arranged above the shelf, the one or more first sidewalls extending between the shelf and the first main surface; and one or more second sidewalls arranged below the shelf, the one or more second sidewalls extending between the shelf and the second main surface; and an NCF arranged on the first main surface, wherein the NCF includes a film groove at an outer edge of the NCF.

In some implementations, a semiconductor device assembly includes a first semiconductor die; and a second semiconductor die arranged on the first semiconductor die to form a die stack, wherein the first semiconductor die includes a wafer assembly comprising one or more wafer layers, the wafer assembly having a first main surface and a second main surface arranged opposite to the first main surface, wherein the wafer assembly includes: a shelf arranged at least partially around an outer periphery of the wafer assembly and arranged at a predefined depth of the wafer assembly, wherein the shelf delineates a change in a cross-sectional width of the wafer assembly; one or more first sidewalls arranged above the shelf, the one or more first sidewalls extending between the shelf and the first main surface; and one or more second sidewalls arranged below the shelf, the one or more second sidewalls extending between the shelf and the second main surface; and an NCF arranged on the first main surface, wherein the NCF includes a film groove at an outer edge of the NCF, wherein the NCF is configured to bond the wafer assembly to the second semiconductor die, and wherein the second semiconductor die is arranged on the NCF.

The foregoing disclosure provides illustration and description but is not intended to be exhaustive or to limit the implementations to the precise forms disclosed. Modifications and variations may be made in light of the above disclosure or may be acquired from practice of the implementations described herein.

The orientations of the various elements in the figures are shown as examples, and the illustrated examples may be rotated relative to the depicted orientations. The descriptions provided herein, and the claims that follow, pertain to any structures that have the described relationships between various features, regardless of whether the structures are in the particular orientation of the drawings, or are rotated relative to such orientation. Similarly, spatially relative terms, such as “below,” “beneath,” “lower,” “above,” “upper,” “middle,” “left,” and “right,” are used herein for ease of description to describe one element's relationship to one or more other elements as illustrated in the figures. The spatially relative terms are intended to encompass different orientations of the element, structure, and/or assembly in use or operation in addition to the orientations depicted in the figures. A structure and/or assembly may be otherwise oriented (rotated 90 degrees or at other orientations), and the spatially relative descriptors used herein may be interpreted accordingly. Furthermore, the cross-sectional views in the figures only show features within the planes of the cross-sections, and do not show materials behind the planes of the cross-sections, unless indicated otherwise, in order to simplify the drawings.

As used herein, the terms “substantially” and “approximately” mean “within reasonable tolerances of manufacturing and measurement.” As used herein, the term “formed” may, depending on the context, refer to a state or a position of a first feature relative to a second feature, and does not imply any specific method or sequence of formation.

Even though particular combinations of features are recited in the claims and/or disclosed in the specification, these combinations are not intended to limit the disclosure of implementations described herein. Many of these features may be combined in ways not specifically recited in the claims and/or disclosed in the specification. For example, the disclosure includes each dependent claim in a claim set in combination with every other individual claim in that claim set and every combination of multiple claims in that claim set. As used herein, a phrase referring to “at least one of” a list of items refers to any combination of those items, including single members. As an example, “at least one of: a, b, or c” is intended to cover a, b, c, a+b, a+c, b+c, and a+b+c, as well as any combination with multiples of the same element (e.g., a+a, a+a+a, a+a+b, a+a+c, a+b+b, a+c+c, b+b, b+b+b, b+b+c, c+c, and c+c+c, or any other ordering of a, b, and c).

No element, act, or instruction used herein should be construed as critical or essential unless explicitly described as such. Also, as used herein, the articles “a” and “an” are intended to include one or more items and may be used interchangeably with “one or more.” Further, as used herein, the article “the” is intended to include one or more items referenced in connection with the article “the” and may be used interchangeably with “the one or more.” Where only one item is intended, the phrase “only one,” “single,” or similar language is used. Also, as used herein, the terms “has,” “have,” “having,” or the like are intended to be open-ended terms that do not limit an element that they modify (e.g., an element “having” A may also have B). Further, the phrase “based on” is intended to mean “based, at least in part, on” unless explicitly stated otherwise. As used herein, the term “multiple” can be replaced with “a plurality of” and vice versa. Also, as used herein, the term “or” is intended to be inclusive when used in a series and may be used interchangeably with “and/or,” unless explicitly stated otherwise (e.g., if used in combination with “either” or “only one of”).

What is claimed is:

1. A method of manufacturing a semiconductor device assembly, the method comprising:
providing a wafer comprising a plurality of die regions, including a first die region and a second die region delineated by a wafer scribe region;
forming a wafer groove in the wafer scribe region, the wafer groove extending from a first wafer surface into the wafer such that a first portion of the wafer groove is located in the first die region and a second portion of the wafer groove is located in the second die region;
forming a non-conductive film (NCF) on the first wafer surface, the NCF covering the wafer groove;
emitting first laser beams into the wafer to form weakened structural regions in the wafer along a scribe line that is aligned with the wafer scribe region;
emitting a second laser beam onto an upper surface of the NCF to form a film groove in the NCF, the film groove being formed over the wafer groove; and
separating the first die region and the second die region along the weakened structural regions to form a first die and a second die, respectively,
wherein separating the first die region and the second die region along the weakened structural regions includes separating the NCF, at the film groove, into two NCF portions.

2. The method of claim 1, wherein forming the wafer groove includes a wafer etching process.

3. The method of claim 1, wherein the second laser beam is focused onto the upper surface of the NCF to remove a portion of the NCF above the wafer groove to form the film groove.

4. The method of claim 2, wherein the second laser beam is a low-power laser.

5. The method of claim 1, wherein the first die and the second die are memory dies.

6. The method of claim 1, wherein the film groove reduces an amount of particulate generated while separating the first die region and the second die region along the weakened structural regions.

7. The method of claim 1, wherein the film groove reduces an amount of damage to sidewalls of the first die and the second die while the first die region and the second die region are being separated along the weakened structural regions.

8. The method of claim 1, wherein the film groove reduces an amount of recoil by the first die and the second die that is induced by separating the first die region and the second die region along the weakened structural regions.

9. The method of claim 1, wherein the first laser beams are associated with a stealth dicing process, and the weakened structural regions are internal modifications formed within the wafer by the first laser beams.

10. The method of claim 1, further comprising:
prior to forming the NCF on the first wafer surface of the wafer, arranging a second wafer surface of the wafer onto an expander, the second wafer surface being opposite to the first wafer surface,
wherein separating the first die region and the second die region along the weakened structural regions includes stretching the expander in opposite lateral directions to cause the first die region and the second die region to separate along the weakened structural regions.

11. The method of claim 1, wherein after separating the first die region and the second die region:
the first die includes a first portion of the NCF, the first portion of the NCF having a first portion of the film groove, and
the second die includes a second portion of the NCF, the second portion of the NCF having a second portion of the film groove.

12. The method of claim 10, wherein after separating the first die region and the second die region:
the first die includes a first portion of the wafer groove, and
the second die includes a second portion of the wafer groove.

13. The method of claim 11, wherein after separating the first die region and the second die region:
the first die includes a first straight sidewall that extends from a bottom of the first portion of the wafer groove to a bottom surface of the first die, and
the second die includes a second straight sidewall that extends from a bottom of the second portion of the wafer groove to a bottom surface of the second die.

14. A method of manufacturing a semiconductor device assembly, the method comprising:
forming a wafer groove in a wafer scribe region of a wafer,
wherein the wafer includes a first die region and a second die region delineated by the wafer scribe region, and
wherein the wafer groove extends from a first wafer surface into the wafer such that a first portion of the wafer groove is located in the first die region and a second portion of the wafer groove is located in the second die region;
forming a non-conductive film (NCF) on the first wafer surface, the NCF being arranged over the wafer groove;
emitting a laser beam onto an upper surface of the NCF to form a film groove in the NCF, the film groove being formed over the wafer groove; and
separating the wafer along a scribe line that is associated with the wafer scribe region such that the first die region is separated from the second die region to form a first die and a second die, respectively,
wherein separating the wafer along the scribe line includes separating the NCF, at the film groove, into two NCF portions.

15. The method of claim 14, wherein the laser beam is focused onto the upper surface of the NCF to remove a portion of the NCF above the wafer groove to form the film groove.

16. The method of claim 14, wherein after separating the wafer:
the first die includes a first portion of the NCF, the first portion of the NCF having a first portion of the film groove, and
the second die includes a second portion of the NCF, the second portion of the NCF having a second portion of the film groove.

17. The method of claim 16, wherein after separating the wafer:
the first die includes a first portion of the wafer groove, and
the second die includes a second portion of the wafer groove.

18. A semiconductor device assembly, comprising:
a semiconductor die comprising a wafer assembly having one or more wafer layers, the wafer assembly having a first main surface and a second main surface arranged opposite to the first main surface, wherein the wafer assembly includes:
a shelf arranged at least partially around an outer periphery of the wafer assembly and arranged at a predefined depth of the wafer assembly, wherein the shelf delineates a change in a cross-sectional width of the wafer assembly;
one or more first sidewalls arranged above the shelf, the one or more first sidewalls extending between the shelf and the first main surface; and
one or more second sidewalls arranged below the shelf, the one or more second sidewalls extending between the shelf and the second main surface; and
a non-conductive film (NCF) arranged on the first main surface, wherein the NCF includes a film groove at an outer edge of the NCF.

19. The semiconductor device assembly of claim 18, wherein the outer edge of the NCF protrudes laterally from the one or more first sidewalls.

20. The semiconductor device assembly of claim 18, wherein the outer edge of the NCF protrudes laterally over the shelf such that the film groove is arranged over the shelf.

21. The semiconductor device assembly of claim 18, wherein the shelf is curved or straight.

22. The semiconductor device assembly of claim 18, wherein the wafer assembly has a first cross-sectional width above the shelf and a second cross-sectional width below the shelf, the first cross-sectional width being less than the second cross-sectional width.

23. The semiconductor device assembly of claim 18, wherein the film groove is concave.

24. The semiconductor device assembly of claim 18, wherein the first sidewalls and the shelf are part of an exterior wafer groove.

25. A semiconductor device assembly, comprising:
a first semiconductor die; and
a second semiconductor die arranged on the first semiconductor die to form a die stack,
wherein the first semiconductor die includes a wafer assembly comprising one or more wafer layers, the wafer assembly having a first main surface and a second main surface arranged opposite to the first main surface, wherein the wafer assembly includes:
a shelf arranged at least partially around an outer periphery of the wafer assembly and arranged at a predefined depth of the wafer assembly, wherein the shelf delineates a change in a cross-sectional width of the wafer assembly;
one or more first sidewalls arranged above the shelf, the one or more first sidewalls extending between the shelf and the first main surface; and
one or more second sidewalls arranged below the shelf, the one or more second sidewalls extending between the shelf and the second main surface; and
a non-conductive film (NCF) arranged on the first main surface, wherein the NCF includes a film groove at an outer edge of the NCF,
wherein the NCF is configured to bond the wafer assembly to the second semiconductor die, and
wherein the second semiconductor die is arranged on the NCF.
